(19) United States
(12) Patent Application Publication
(10) Pub. No.: US 2008/0247130 A1
(43) Pub. Date: Oct. 9, 2008

(54) COMPUTER ENCLOSURE INCORPORATING DRIVE BRACKET

(75) Inventor: YUN-LUNG CHEN, Tu-Cheng (TW)

Correspondence Address: PCE INDUSTRY, INC.;ATT. CHENG-JU CHIANG, 458 E. LAMBERT ROAD, FULLERTON, CA, 92835, US

(73) Assignee: HON HAI PRECISION INDUSTRY CO., LTD., Tu-Cheng (TW)

(21) Appl. No.: 11/757,407

(22) Filed: Jun. 4, 2007

(30) Foreign Application Priority Data
Apr. 5, 2007 (CN) 200720200231.2

(51) Int. Cl. G06F 1/16; A47B 81/00; H05K 7/00

(52) U.S. Cl. 361/685; 312/223.2; 361/726

(57) ABSTRACT

A computer enclosure includes a chassis (10), a drive bracket (20), and a cover panel (30) for covering the chassis after the drive bracket is mounted in the chassis. The chassis includes a pair of side panels (14), and a pair of supporting plates (16) being formed beside interior sides of the side panels respectively. At least one slot (161 or 163) is defined in each of the supporting plates, and the slot includes a flat sliding portion (161b or 163b) and an arc-shaped fixing portion (161c or 163c). The drive bracket includes a pair of side plates each with at least a stud (221) protruding therefrom corresponding to the slot of the chassis. After each stud of the drive bracket slides along the sliding portion of the corresponding slot and then engages within the fixing portion of the corresponding slot, the cover panel is slidably attached to the chassis, whereby the drive bracket is mounted in the chassis.

### BACKGROUND

1. Field of The Invention

The present invention relates to computer enclosures, and more particularly to a computer enclosure incorporating a drive bracket.

2. Description of Related Art

When a conventional computer is assembled, a drive bracket is firstly mounted in a computer enclosure. Then data storage devices such as a hard disk drive (HDD), a floppy disk drive (FDD), and a compact disk read only memory (CD-ROM) drive are attached to the drive bracket.

Users and manufacturers desire the drive bracket to be installed in the computer enclosure quickly and easily. The drive bracket is typically secured to a computer enclosure by riveting or by using a number of screws. However, such means are cumbersome and time-consuming. Extra components such as rivets or screws increase costs. Furthermore, during assembly, extra operating space for attaching the rivets or screws is required.

Computers are continually being made smaller and smaller. So all space inside a computer enclosure is precious and should be fully utilized, such as space under a drive bracket. However, electronic components located under the drive bracket need to be maintained or replaced from time to time, requiring removal of the drive bracket.

What is needed, therefore, is a computer enclosure having a simple structure for easy installation and removal of drive brackets thereof.

### SUMMARY OF THE INVENTION

A computer enclosure includes a chassis, a drive bracket, and a cover panel for covering the chassis after the drive bracket is mounted in the chassis. The chassis includes a pair of side panels, and a pair of supporting plates being formed beside interior sides of the side panels respectively. At least one slot is defined in each of the supporting plates. The slot includes a flat sliding portion and an arc-shaped fixing portion. The drive bracket includes a pair of side plates each with at least a stud protruded therefrom corresponding to the slot of the chassis. Wherein after each stud of the drive bracket slides along the sliding portion of the corresponding slot and then engages within the fixing portion of the corresponding slot, the drive bracket is mounted in the chassis.

Other advantages and novel features will be drawn from the following detailed description of preferred embodiments with attached drawings, in which:

### BRIEF DESCRIPTION OF THE DRAWINGS

FIG. 1 is an exploded, isometric view of a computer enclosure incorporating a drive bracket in accordance with a preferred embodiment of the present invention;

FIG. 2 is a pre-assembled view of FIG. 1; and

FIG. 3 is an assembled view of FIG. 1.

### DETAILED DESCRIPTION OF THE INVENTION

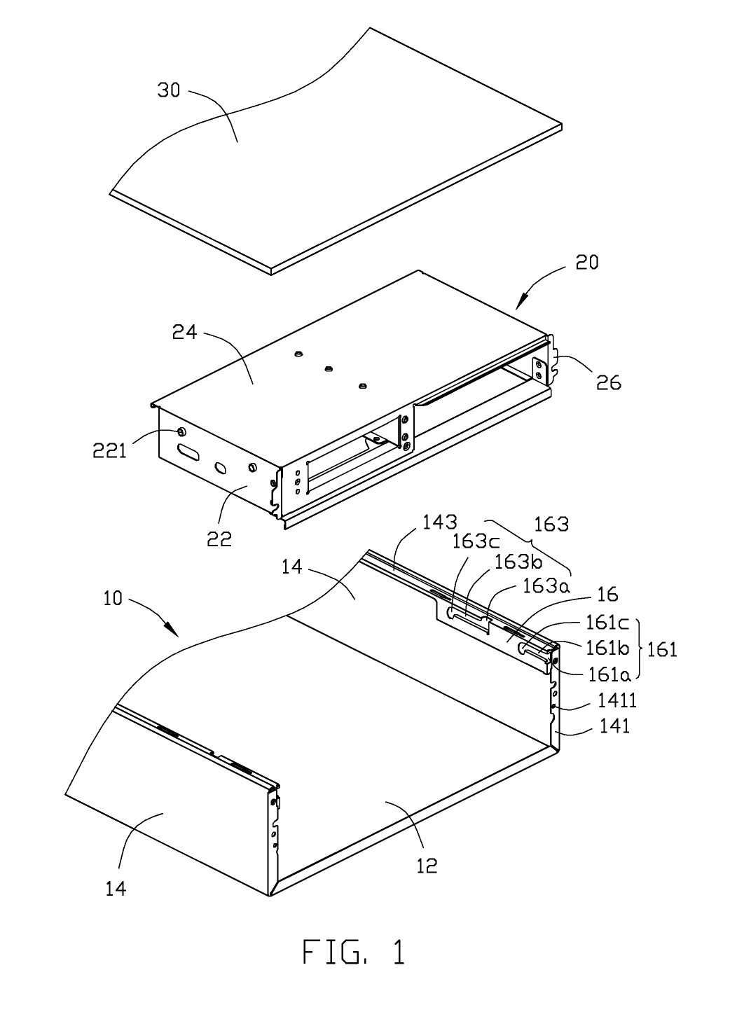

Referring to FIG. 1, a computer enclosure in accordance with the preferred embodiment of the present invention comprises a chassis 10, a drive bracket 20, and a cover panel 30 configured for attaching to the chassis 10 after the drive bracket 20 is mounted in the chassis 20.

The chassis 10 includes a bottom panel 12, a pair of upright side panels 14 extending from two opposite sides of the bottom panel 12, and a pair of supporting plates 16 formed beside interior sides of the side panels 14 respectively. A pair of top flanges 143 extends perpendicularly inwards from top edges of the side panels 14 respectively. A pair of front flanges 141 extends perpendicularly inwards from front edges of the side panels 14 respectively. Each supporting plate 16 includes a body board parallel to the side panel 14 extending perpendicularly downwards from a corresponding top flange 143, and a front hem flatly connected with a corresponding front flange 141. Each supporting plate 16 defines a pair of slots 161,163 therein. The slots 161 each include an enlarged entrance portion 161a defined in the front hem of the supporting plate 16, and a flat sliding portion 161b, and an arc-shaped fixing portion 161c both defined in the body board of the supporting plate 16. The slots 163 each include an enlarged entrance portion 163a defined in the corresponding top flange 143, and a flat sliding portion 163b, and an arc-shaped fixing portion 163c both defined in the body board of the supporting plate 16. A plurality of securing holes 1411 is defined in the front flange 141 adapted for securing a front panel to the chassis 10.

The drive bracket 20 includes a pair of opposite side plates 22, and a top plate 24 perpendicularly connected therebetween. A pair of studs 221 corresponding to the slots 161,163 protrudes from each side plate 22 of the drive bracket 20. A pair of resisting pieces 26 extends perpendicularly outwards from the side plates 22 of the drive bracket 20 respectively. A length of the studs 221 protruded from the side plates 22 of the drive bracket 20 is less than a width of the top flange 143 of the chassis 10.

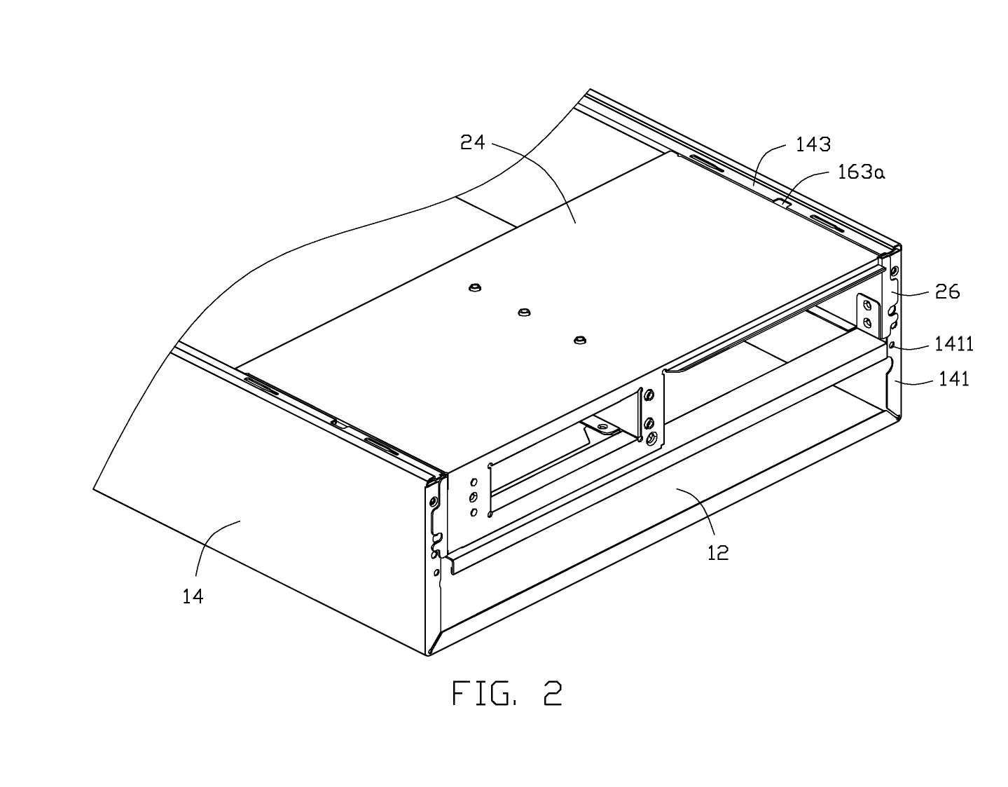

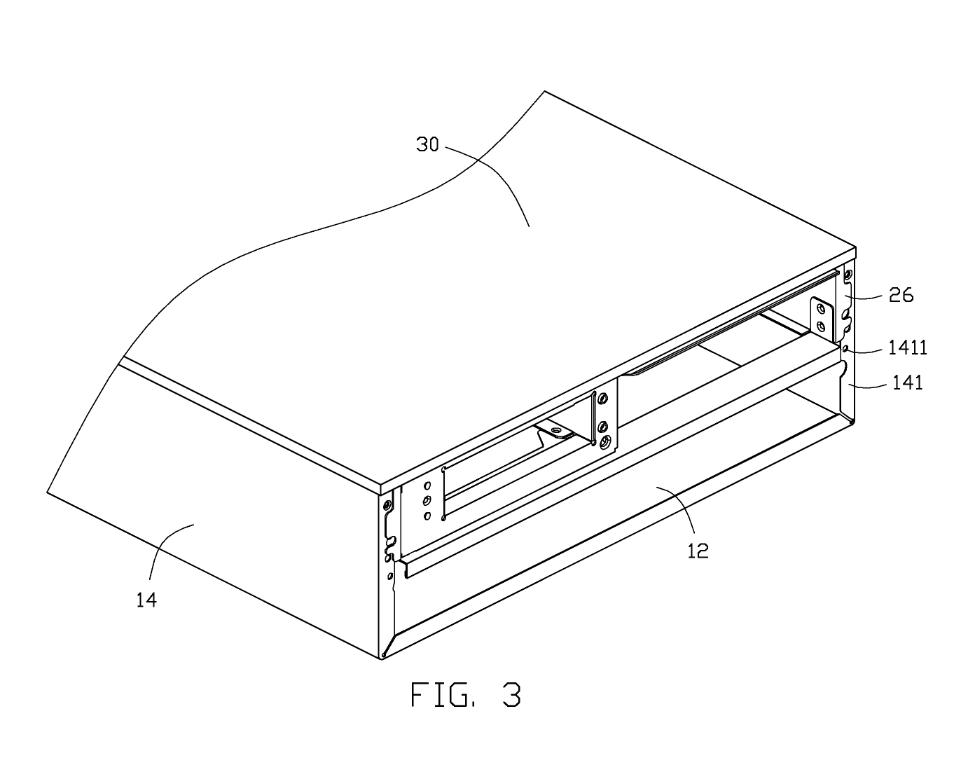

Referring also to FIGS. 2 and 3, in assembly, the studs 221 of the drive bracket 20 slide along the sliding portions 161b,163b from the entrance portions 161a, 163a of the corresponding slots 161,163 until engaging within the fixing portions 161c,163c of the corresponding slots 161,163. The drive bracket 20 is mounted between the supporting plates 16 of the chassis 10 and the resisting pieces 26 abut against the front flange 141 of the chassis 10. The cover panel 30 is finally slidably secured to the chassis 10 and abutting against the drive bracket 20 toward the bottom panel 10 for further securely mounting the drive bracket 20.

In disassembly, the cover panel 30 is firstly moved from the chassis 10, and then the studs 221 of the drive bracket 20 slide from the slots 161,163 of the chassis 20 along a reverse route relative to an assembly route described above. Thus, the drive bracket 20 is moved from the chassis 10.

It is to be understood, however, that even though numerous characteristics and advantages have been set forth in the foregoing description of preferred embodiments, together with details of the structures and functions of the preferred embodiments, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A computer enclosure comprising:
a chassis comprising a bottom panel, a pair of upright side panels extending from two opposite sides of the bottom panel respectively, and a pair of supporting plates being formed beside interior sides of the side panels respectively, at least one slot being defined in each of the supporting plates, each slot comprising a flat sliding portion and an arc-shaped fixing portion communicated with an end of the sliding portion;
a drive bracket comprising a pair of side plates each with at least a stud protruding therefrom corresponding to said at least one slot of the chassis; wherein the studs of the drive bracket are capable of sliding along the sliding portion of the corresponding slot in a first direction to be engaged within the fixing portion of the corresponding slot in the first direction whereby the drive bracket is mounted between the supporting plates of the chassis and is locked in the first direction; and
a cover panel configured for covering the chassis and locking the drive bracket in the chassis in a second direction perpendicular to the side panel and the first direction.

2. The computer enclosure as described in claim 1, wherein the slot further comprises an entrance opening communicated with another end of the sliding portion for allowing exit and entrance of the corresponding stud of the drive bracket.

3. The computer enclosure as described in claim 2, wherein a pair of top flanges bends perpendicularly inwards from top edges of the side panels of the chassis respectively; the supporting plates extend perpendicularly downwards from the top flanges of the chassis respectively; the entrance opening is defined in the top flange connected with the supporting plate where the slot is defined.

4. The computer enclosure as described in claim 2, wherein the supporting plates each comprises a body board parallel to the side panels of the chassis and a front hem extending from a front edge of the body board, and the entrance opening is defined in a corresponding front hem.

5. The computer enclosure as described in claim 4, wherein the chassis further comprises a pair of front flanges extending perpendicularly from the side panels respectively, the front hem of each supporting plate is flatly connected with a corresponding front flange of the chassis.

6. The computer enclosure as described in claim 5, wherein the drive bracket further comprises a pair of resisting pieces resisting against the front flanges of the chassis when the drive bracket is mounted between the supporting plates.

7. The computer enclosure as described in claim 4, wherein a distance between the side plates of the drive bracket is equal to that between the body boards of the supporting plates of the chassis.

8. A computer enclosure comprising:
a chassis with a pair of opposite supporting plates each defining a slot therein, the slots each comprising an entrance portion, an arc-shaped fixing portion, and a flat sliding portion connected between the entrance portion and the fixing portion; and
a drive bracket comprising two opposite side plates each having a stud corresponding to one of the slots of the chassis protruding therefrom;
wherein the studs of the drive bracket are capable of entering into the entrance portion in a first direction and sliding along the sliding portion in a second direction to finally move in the first direction again to engage with the fixing portion of the corresponding slot, whereby the drive bracket is mounted between the supporting plates of the chassis.

9. The computer enclosure as described in claim 8, wherein the entrance portions of said slots are located above said sliding portions thereof.

10. The computer enclosure as described in claim 8, wherein each of the supporting plates further defines another slot therein, said another slots each comprising a front entrance portion, a rear arc-shaped fixing portion, and a sliding portion connected therebetween, and each of the side plates of the drive bracket further comprises a stud capable of entering into the front entrance portion in the second direction and sliding along the sliding portion in the second direction to finally move in the first direction again to engage with the fixing portion of the corresponding slot.

11. The computer enclosure as described in claim 8, further comprises a cover panel configured for covering on the chassis after the drive bracket is mounted between the supporting plates of the chassis.

12. The computer enclosure as described in claim 8, wherein the drive bracket comprises a pair of resisting pieces resisting against front flanges of the chassis respectively after the drive bracket is mounted.

13. The computer enclosure as described in claim 8, wherein the chassis further comprises a pair of side panels beside the supporting plates respectively, a top flange extends perpendicularly from each side panel and connects with the corresponding supporting plate.

14. The computer enclosure as described in claim 13, wherein a length of the studs protruded from the side plates of the drive bracket is less than a width of the top flange of the chassis.

15. A computer enclosure comprising:
a chassis comprising a bottom panel, a pair of side panels extending from opposite sides of the bottom panel respectively, and a pair of supporting plates being fixed at interior sides of the side panels respectively, a pair of slots being defined in each of the supporting plates, each slot comprising a sliding portion and an arc-shaped fixing portion communicated with an end of the sliding portion;
a drive bracket comprising a pair of side plates each having a pair of studs protruding therefrom and corresponding to the slots of the chassis respectively, wherein the studs of the drive bracket are capable of sliding along the sliding portion of the corresponding slot in a front-and-back direction to be engaged within the fixing portion of the corresponding slot in the front-and-back direction, whereby the drive bracket is mounted between the supporting plates of the chassis in a left-and-right and is locked by the fixing portion of the slots in the front-and-back direction; and
a cover panel slidably attached to the chassis and abutting against the drive bracket in an up-and-down direction to thereby lock the drive bracket within the chassis in the up-and-down direction.

16. The computer enclosure as claimed in claim 15, wherein each of the supporting plates comprises a top flange extending perpendicularly from the corresponding side panel and a body board extending perpendicularly from the top flange, the top flange being parallel to the bottom panel and the cover panel, the body board being parallel to the side panels.

17. The computer enclosure as claimed in claim 15, wherein one of the pair of slots further comprises an entrance portion defined at the top flange and communicated with the sliding portion configured for entering of the corresponding stud in the up-and-down direction.

18. The computer enclosure as claimed in claim 16, wherein the other one of the pair of slots further comprises an entrance portion communicated with the sliding portion configured for entering of the corresponding stud in the front-and-back direction.
